(19) United States
(12) Patent Application Publication
(10) Pub. No.: US 2022/0209090 A1
(43) Pub. Date: Jun. 30, 2022

(54) THERMOELECTRIC DEVICE WITH ELECTRICALLY CONDUCTIVE COMPLIANT MECHANISM CONNECTOR

(71) Applicant: Nanohmics, Inc., Austin, TX (US)

(72) Inventors: Steve M. Savoy, Austin, TX (US); Giri Joshi, Austin, TX (US); Michael McAleer, Austin, TX (US); Rey Guzman, Austin, TX (US); Scott Smith, Lago Vista, TX (US); Robert Pearsall, Austin, TX (US); Joshua C. Ruedin, Austin, TX (US)

(73) Assignee: Nanohmics, Inc., Austin, TX (US)

(21) Appl. No.: 17/561,002

(22) Filed: Dec. 23, 2021

Related U.S. Application Data
(60) Provisional application No. 63/132,426, filed on Dec. 30, 2020.

(51) Int. Cl. H01L 35/10; H01L 35/32; H01L 25/04

(52) U.S. Cl. CPC H01L 35/10; H01L 25/04; H01L 35/32

(57) ABSTRACT

Thermoelectric devices have an electrically conductive connector for connecting thermoelectric modules. The electrically conductive connector is a compliant mechanism having a first connecting region and a second connecting region that are rigid bodies and an elastically deformable region that is a flexible member positioned between the first and second connecting regions. The electrically conductive compliant mechanism connector enables facile manufacture and assembly of thermoelectric devices of various sizes and shapes that are conformable to irregularly shaped objects and body parts.

### CROSS REFERENCE TO RELATED APPLICATIONS

This application claims the benefit of U.S. Provisional Patent Application No. 63/132,426 filed Dec. 30, 2020, which is incorporated by reference herein in its entirety.

### STATEMENT REGARDING FEDERALLY SPONSORED RESEARCH

The invention was made, in part, with government support under Contract No. NNX17CP04C awarded by NASA and Contract No. N00014-19-9-0016 awarded by the U.S. Navy. The government has certain rights in the invention.

### TECHNICAL FIELD OF THE DISCLOSURE

The invention relates to thermoelectric devices and more particularly to thermoelectric devices having an electrically-conductive, compliant mechanism for connecting thermoelectric modules.

### GENERAL DESCRIPTION

The thermoelectric effect is the conversion of a temperature difference to an electric potential difference or the conversion of an electric potential difference to a temperature difference. Thermoelectric generators (TEGs), which operate under the principles of the Seebeck effect, generate an electric current from temperature differences. Thermoelectric coolers (TECs), which operate under the principles of the Peltier effect, generate a temperature difference. i.e., transfer heat from one location to another location using an applied electric current. TECs may be electrically connected to a battery or other electrical source for generating a temperature difference and can be used for heating or cooling. TEGs may be electrically connected to a power storage circuit for storing generated electricity, such as for example a battery charger.

TEG and TEC devices are commercially available and are generally made with alternating n-type and p-type semiconductor material referred to as thermoelectric elements (TEEs). Commercial TEEs can be composed of thin film, epitaxial layers or bulk materials such as extruded ingots that are cut to size. Conventional methods for manufacturing bulk TEEs have included melt extrusion in the form of single and polycrystalline phases followed by mechanical processing to the desired shape of the TEE prior to placement for making a thermoelectric module (TEM). Alternative manufacturing approaches include vacuum deposition such as sputtering, electroplating, electrochemical and other slurry packing and compaction methods followed by sintering thermoelectric powder material at high temperature and high pressure.

In many commercial embodiments, TEMs are frequently made with TEEs that are cuboid and are mechanically assembled in an alternating polarity (i.e., p-type and n-type) arrangement. The TEEs are arrayed, a low contact resistance layer is added, and TEEs are bonded to electrodes. In conventional methods of making TEMs, the arrayed TEEs are positioned between electrically insulating substrates that are typically rigid ceramic substrates that bear a patterned serpentine electrode for electrically connecting the TEEs and for application or collection of the electric current. These types of mechanically assembled TEMs may be used as TEC/TEG devices that are generically referred to as thermoelectric devices (TEDs). Commercial TEDs may have one or more TEMs.

Exemplary applications of TEC/TEG devices include generating electric current from body heat, heating and/or cooling a body part, heating and/or cooling objects, recovery of waste heat from vehicular and commercial mechanical components, and generation of electricity for spacecraft and other remote electrical components. Electrical current generation and heat transfer for cooling or heating may be improved by enhancing thermal contact between a TED such as a TEM and a surface to which the TEM is applied. A conformable TED can be useful for enhancing the thermoelectric effect when applied to a non-planar or non-uniform surface, such as for example a part of a human or animal body or another structure or a part of a structure including but not limited to a structure that is irregularly shaped.

Previous strategies for improving application of TEDs to irregular surfaces and structures have included affixing n-type and p-type TEs to a flexible substrate of a TEM or embedding n-type and p-type TEs in a flexible matrix of a TEM. These devices are generally not suitable for facile addition and removal of TEMs for enlarging or reducing the size of a TED, and they are typically only useful with gently curved surfaces such as a large-diameter, cylindrically shaped structure like a pipe.

Embodiments of TEDs such as TEMs described herein are adapted for application to irregularly shaped surfaces and structures so as to increase thermal contact between a TED and the surface to which it is applied. Embodiments described herein enable facile alteration of TED conformation, allowing for enlarging and reducing the size of a TED as required for a specific application and for modifying the shape and size of a TED as desired.

Some embodiments described in the disclosure are directed to an electrically conductive connector for electrically and mechanically connecting TEMs that are useful as TEDs. In embodiments described herein, the electrically conductive connector is a compliant mechanism comprising a first connecting region, a second connecting region, and an elastically deformable region between the first connecting region and the second connecting region. The first connecting region and/or the second connecting region may be rotatably and releasably coupled to a TEM. In some embodiments, one of the first connecting region or the second connecting region may be non-rotatably attached to a TEM. In some aspects, one connecting region is rotatably connected to a TEM and another connecting region is non-rotatably coupled to another TEM. The electrically conductive connector is useful for connecting at least two adjacent TEMs, which may be part of a TED. In some embodiments, TEMs connected with an electrically conductive connector described herein can be useful in applications that may benefit from flexibility, conformability, and/or high surface area thermal contact of a TED. Embodiments are also directed to TEMs that are connected with the electrically conductive connector and TEDs that comprise a plurality of TEMs connected with the electrically conductive connector.

In some embodiments a TED may comprise a plurality of electrically connected TEMs, wherein at least a first and a second TEMs are electrically and mechanically connected by an electrically conductive connector, the electrically conductive connector being a compliant mechanism and comprising a first connecting region connected to a first TEM, a second connecting region connected to a second TEM, and an elastically deformable region between the first connecting region and the second connecting region, wherein at least one of the first or second connecting regions is releasably and rotatably connected to the respective first or second TEM. In some embodiments of a TED, the first connecting region is releasably and rotatably connected to the first TEM, and the second connecting region is fixedly connected to the second TEM. In some embodiments of a TED, the first and second connecting regions are releasably and rotatably connected to the respective first and second TEMs with a plug-receptacle connection. In some embodiments, connecting regions that are connected to a TEM may be releasably connected or may be fixedly connected. In some aspects, a connecting region that is releasably connected to a TEM may be non-rotatably connected and in some aspects may be rotatably connected. In some aspects, a connecting region configured for releasable connection may be configured as a plug-receptacle connection.

In some embodiments, adjacent TEMs in a TED may be electrically and mechanically connected by a plurality of electrically conductive connectors, each of the plurality of electrically conductive connectors being a compliant mechanism and comprising a first connecting region connected to the first thermoelectric module, a second connecting region connected to the second thermoelectric module, and an elastically deformable region between the first connecting region and the second connecting region. In some aspects, the first connecting region in each of the plurality of electrically conductive connectors is releasably and rotatably connected to the first thermoelectric module. In some aspects, the second connecting region in each of the plurality of electrically conductive connectors is releasably and rotatably connected to the second thermoelectric module.

In some embodiments, a TED as described herein my further comprise at least one heat dissipation structure and/or at least one fan. In some aspects, TEMs comprise thermally conductive substrates that are printed circuit boards. TEMs may be positioned in a carrier frame, in some aspects. In some embodiments, a medical device may contain a TED described herein. An article of apparel may also comprise a TED as described herein.

The specification is most thoroughly understood in light of the teachings of the specification and references cited within the specification. It should be understood that the drawings, detailed description, and specific examples, while indicating specific embodiments of the invention, are given by way of illustration only, since various changes and modifications within the spirit and scope of the invention will become apparent from this detailed description to those skilled in the art.

Any section headings used herein are for organizational purposes only and are not to be construed as limiting the subject matter described. All documents, or portions of documents, cited in this application, including but not limited to patents, patent applications, articles, books, and treatises, are hereby expressly incorporated by reference in their entirety for any purpose. To the extent publications and patents or patent applications incorporated by reference contradict the invention contained in the specification, the specification will supersede any contradictory material.

### BRIEF DESCRIPTION OF THE DRAWINGS

The following drawings form part of the present specification and are included to further demonstrate certain aspects of the invention. Embodiments of the invention may be better understood by reference to one or more of these drawings in combination with the detailed description of specific embodiments presented herein. The use of a letter following an element number is for descriptive purposes only. For example, 201a and 201b each refer to a TEM 201, but may refer to different modules in a figure as an aid in understanding the description of the figure.

FIGS. 1A-1C are perspective views of exemplary embodiments of an electrically conductive connector.

FIG. 2 shows an exemplary embodiment of an electrically conductive connector in electrical and mechanical connection with adjacent TEMs.

FIG. 3 shows an exemplary embodiment of an electrically conductive connector that may be useful for making two releasable connections between an electrically conductive connector and two adjacent TEMs.

FIGS. 4A-4I depict exemplary embodiments for connecting two or more adjacent modules with electrically conductive connectors.

FIGS. 5A-5E are schematic depictions of exemplary embodiments of a TED with rotatable connections between TEMs.

FIGS. 6A-6G show exemplary embodiments of an electrically conductive connector.

FIGS. 7A-7B show embodiments of a carrier frame and associated structures.

FIGS. 8A-8B illustrate embodiments of TEMs positioned in a carrier frame.

FIG. 9 schematically illustrates an exemplary embodiment of a TED.

FIGS. 10A-10B depict an embodiment of a TED that can be useful in thermoelectric applications with a curved surface.

FIG. 11 schematically depicts an embodiment of a TED affixed to a body part.

FIGS. 12A-12D depict embodiments in which a carrier frame is used to incorporate a TED with a substrate material.

FIG. 13 shows an exemplary embodiment of an article of apparel fitted with two TEDs.

FIGS. 14A-14B are schematic representations of exemplary arrangements of TEMs connected in two dimensions by electrically conductive connectors.

FIGS. 15A-15D illustrate the conformability of a TED comprising a plurality of connected TEMs.

### DETAILED DESCRIPTION

Reference will now be made in detail to certain exemplary embodiments, some of which are illustrated in the accompanying drawings. Certain terms used in the application are first defined. Additional definitions are provided throughout the application.

The symbol “˜”, which means “approximately”, and the terms “about” or “approximately” are defined as being close to, as would be understood by one of ordinary skill in the art. In an exemplary non-limiting embodiment, the terms are defined to mean within 10%, preferably within 5%, more preferably within 1%, and most preferably within 0.5% of a stated value. For example, “about 4” or “˜ 4” means from 3.6-4.4 inclusive of the endpoints 3.6 and 4.4, and “about 1 nm” means from 0.9 nm to 1.1 nm inclusive of the endpoints 0.9 nm and 1.1 nm. All ranges described herein are inclusive of the lower and upper limit values.

As used herein, the term “equal” and its relationship to the values or characteristics that are “substantially equal” would be understood by one of skill in the art. Typically, “substantially equal” can mean that the values or characteristics referred to may not be mathematically equal but would function as described in the specification and/or claims. As used herein, “substantially” is meant to mean “approximately”, not necessarily “perfectly”. The term “substantially” and its variations are defined to include ranges within 10%, within 5%, within 1%, or within 0.5%.

As used herein, the phrases “at least one of A or B” and “at least one of A and B” are each meant to include one or more of only A, one or more of only B, or any combination and number of A and B. Any combinations having a plurality of one or more of any of the elements or steps listed are also meant to be included by the use of these phrases. For example, the combinations of 1A and 1B, 2A and 1B, 2B and 1A, and 2B and 2A are included. Similar phrases for longer lists of elements or steps (e.g., “at least one of A or B or C” and “at least one of A and B and C”) are also contemplated to indicate one or more of either element or step alone or any combination including one or more of any of the elements or steps listed.

The compositions and methods for their use can “comprise,” “consist essentially of,” or “consist of” any of the compositions or steps disclosed throughout the specification.

It is contemplated that any embodiment discussed herein can be implemented with respect to any method or composition of the invention, and vice versa. Furthermore, compositions and kits of the invention can be used to achieve methods of the invention.

As used herein, the term “thermoelectric device” or “TED” refers to a “thermoelectric module” or “TEM” or a plurality of TEMs that may be configured to operate as a TEC or a TEG, and the terms are used interchangeably herein. As is known in the art, a variety of electrical connections may be used for assembling and using a TED. For example, positive and negative electrical leads may be used for connecting a TED such as a TEM to a battery or other power source or power storage option. In some aspects, an electrical connection need not be a physical connection.

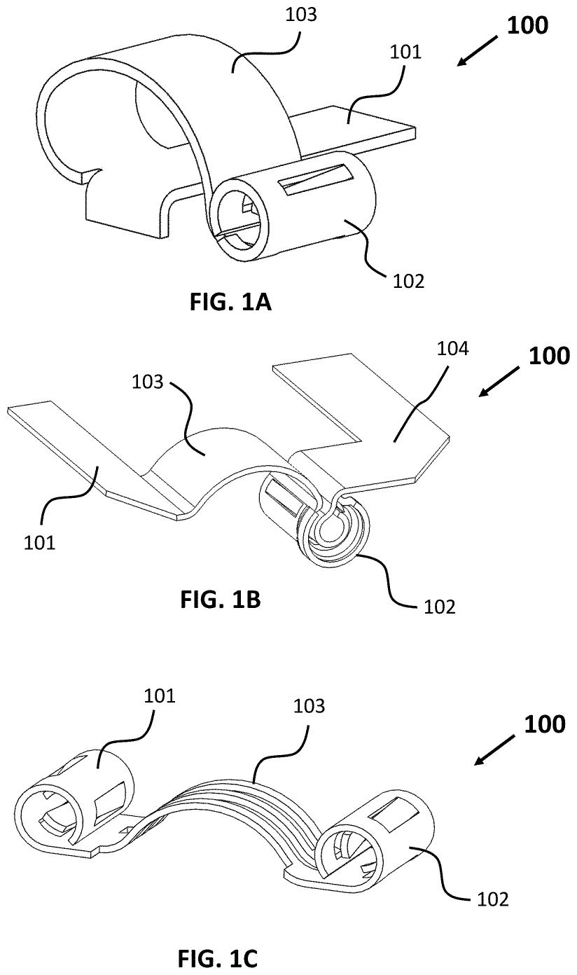

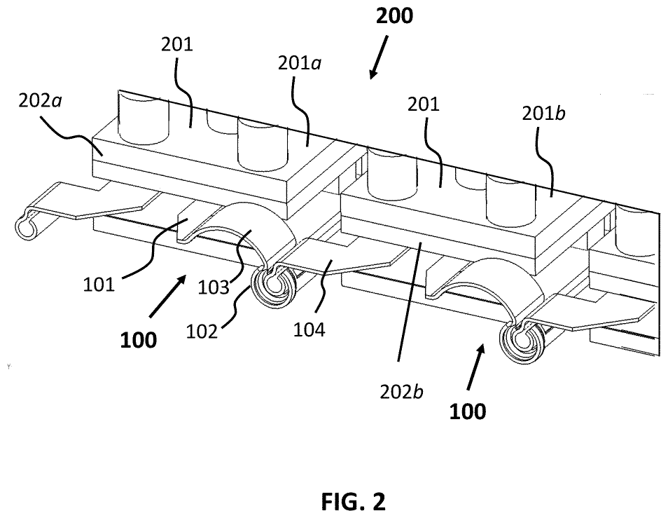

FIGS. 1A-1C are perspective views of exemplary embodiments of electrically conductive connector 100 useful for electrically and mechanically connecting TEMs. In embodiments described herein, electrically conductive connector 100 is a compliant mechanism comprising first connecting region 101, second connecting region 102, and elastically deformable region 103 between first connecting region 101 and second connecting region 102. In some aspects, one or more connecting region 101, 102 may be configured to connect with an electrical lead 104, as shown in FIG. 1B for connecting region 101 and electrical lead 104. In some aspects, electrical lead 104 is part of TEM 201 and is connected with a positive or negative terminal of the TEM 201 (FIG. 2). In some aspects, one or more connecting region 101, 102 may itself connect to a positive or negative terminal of a TEM 201. For example, connecting region 101 in FIGS. 1A and 1B is configured for attachment to a TEM 201.

As used herein, “compliant mechanism” refers to a mechanism that gains at least some of its mobility from the deflection of one or more flexible members. This is in contrast to a rigid body mechanism that gets its motion only from moveable joints of rigid bodies, such as for example physical pins and hinges sliding against one another. (see Linβ et al., 2019 which is incorporated by reference herein in its entirety). In embodiments described herein, electrically conductive connector 100 has first 101 and second 102 connecting regions that are rigid bodies and elastically deformable region 103 that is a flexible member positioned between first connecting region 101 and second connecting region 102. In embodiments described herein, electrically conductive connector 100 gains at least some of its mobility from the deformation of elastically deformable region 103. In some aspects, electrically conductive connector 100 may derive all of its mobility from the deformation of elastically deformable region 103.

As used herein, unless specifically defined elsewhere “deformation” refers to a change or alteration in the shape of an object. An object that is deformable can undergo deformation in response to an applied force. Herein, “elastic deformation” refers to a reversible change or alteration in the shape of an object in response to an applied force. An object that is “elastically deformable” can undergo elastic deformation. Deformation of an elastically deformable object may be due to an applied force and uses energy. Energy is stored in the form of strain energy in the deformed flexible object. If the energy comes back out when applied forces are released, that deformation is called “elastic deformation”.

An elastically deformable object (such as elastically deformable region 103 of electrically conductive connector 100) that undergoes elastic deformation in response to an applied force spontaneously returns to its original shape or substantially original shape when the applied force causing the deformation is removed. This spontaneous return is due to the stored strain energy in the deformed object. Stored strain energy may also be referred to as “elastic potential energy”. Deformation of elastically deformable region 103 may be the result of an applied force that causes, by way of example only, one or more than one of bending, contracting, stretching, twisting, compression, elongation, expansion, and distortion of the region. Deformation by an applied force may cause a change in one or more spatial dimension of elastically deformable region 103, including, by way of example only, one or more than one of shape, length, angle, volume, and width as compared to the original value or values of the one or more spatial dimensions when no force is applied to elastically deformable region 103. Deformation may be caused by any force applied to elastically deformable region 103 that is sufficiently strong to cause a change in one or more spatial dimension.

For optimal operability of a conformable TED comprising TEMs connected by electrically conductive connector 100, elastically deformable region 103 should not undergo plastic deformation during normal use and should not be so brittle as to break during normal use. Plastic deformation means that when an object is deformed by an applied force (for example by stretching) it remains deformed or stretched when the applied force causing the deformation is removed.

FIG. 2 shows an exemplary embodiment of an electrically conductive connector 100 in electrical and mechanical connection with adjacent TEMs 201. The embodiment in FIG. 2 is the electrically conductive connector 100 depicted in FIGS. 1B and 1s shown in electrical and mechanical connection with adjacent TEMs 201 (201a, 201b) of an exemplary embodiment of TED 200. The term “adjacent” or “adjacent to,” as used herein, includes “next to”’ and “adjoining”. For example, adjacent TEMs 201a and 201b are TEMs positioned next to each other and separated by a space and having no other TEMs between the adjacent TEMs. In some aspects, TEMs 201 that are adjacent and connected by electrically conductive connector 100 may be referred to herein as adjoined, connected, electrically connected, coupled, and electrically coupled TEMs. In many aspects, adjacent TEMs 201 are connected by one or more electrically conductive connector 100. When first 101 and second 102 connecting regions, are connected to adjacent TEMs 201a and 201b, electrically conductive connector 100 is considered as being “connected” or “coupled” to the adjacent TEMs. As used herein, “coupled” means “connected” or “attached” and the terms may be used interchangeably. In some aspects, connected TEMs, may be mechanically connected, electrically connected, or both mechanically and electrically connected. In some embodiments, a connecting region 101, 102 may be releasably coupled to a TEM 201, meaning that the connecting region 101, 102 can be relatively easily removed, detached, or uncoupled from TEM 201. In some aspects, a connecting region 101, 102 that is releasably coupled to a TEM 201 may be rotatably coupled or non-rotatably coupled. In some aspects a connecting region 101, 102 may be fixedly connected to a TEM 201. As used herein “fixedly” connected or “fixedly” coupled means connected, attached, or placed so as to be firm and not readily movable. A connecting region that is fixedly connected to a TEM does not move relative to the TEM. A connecting region 101, 102 that is fixedly connected to a TEM is non-rotatably coupled to the TEM.

In the exemplary embodiment of FIG. 2, electrically conductive connector 100 comprises first connecting region 101 and second connecting region 102 and is electrically and mechanically connected to first TEM 201a and second TEM 201b respectively. Here, first connecting region 101 is a rigid body configured as a flat blade that can be fixedly connected to TEM 201a for making an electrical and mechanical connection to TEM 201a. Second connecting region 102 is a rigid body configured as a receptacle for receiving a plug that is part of electrical lead 104 of TEM 201b, thereby establishing electrical and mechanical connection with TEM 201b. Some exemplary means for fixedly connecting a connecting region 101, 102 to a TEM 201 include soldering, brazing, conductive paint, and conductive adhesion. In this exemplary embodiment, electrical and mechanical connection between electrically conductive connector 100 and first TEM 201a and second TEM 201b is made near TEM end 202 (here ends 202a and 202b). In some embodiments of a TED 200, one connecting region of first 101 and second 102 connecting regions is fixedly connected to a TEM 201 and the other is releasably and rotatably coupled to an adjacent TEM 201.

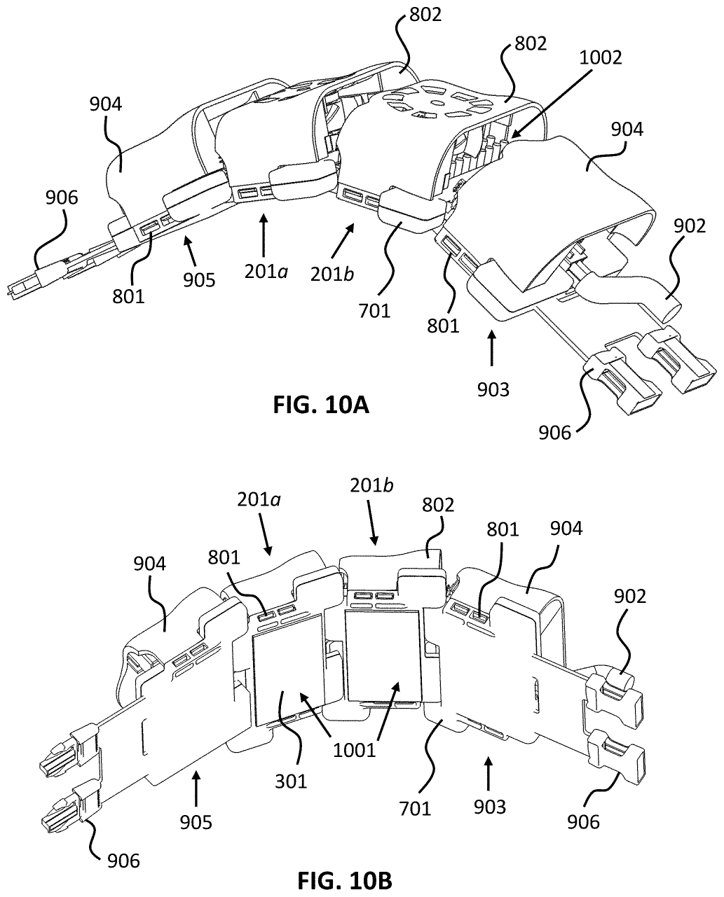

In some embodiments, electrically conductive connector 100 is connected to adjacent TEMs 201a and 201b by at least one connection that is a rotatable and releasable connection between one of connecting regions 101 or 102 and the respective TEM 201a or 201b. By way of example only, electrically conductive connectors in FIGS. 1A-10 may be useful for such embodiments. In some embodiments, the connection between first connecting region 101 and first TEM 201a and the connection between second connecting region 102 and second TEM 201b are each rotatable and releasable connections. In these embodiments, the first 101 and second 102 connecting regions may be said to be rotatably and releasably “connected” or “coupled” to a TEM 201. By way of example only, the electrically conductive connector 100 in FIG. 10 may be useful for such embodiments. In some aspects, a rotatable and releasable connection may be provided by a plug-receptacle connection.

In some embodiments, a TED 200 comprises a plurality of electrically connected TEMs 201, wherein at least a first 201a and a second 201b TEMs are electrically and mechanically connected by an electrically conductive connector 100, the electrically conductive connector 100 being a compliant mechanism and comprising a first connecting region 101 coupled to a first TEM 201, a second connecting region 102 coupled to a second TEM 201, and an elastically deformable region 103 between the first connecting region 101 and the second connecting region 102, wherein at least one of the first and second connecting regions is releasably and rotatably coupled to the respective first or second thermoelectric module.

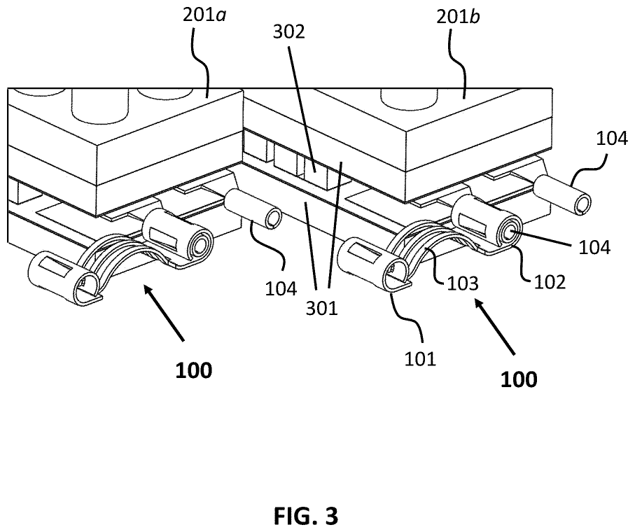

FIG. 3 shows an exemplary embodiment of an electrically conductive connector 100 for connecting adjacent TEMs 201a, 201b and that may be useful for making a releasable connection between the electrically conductive connector and each of the adjacent TEMs. Also depicted in FIG. 3 are TEEs 302 positioned between thermally conductive substrates 301 of TEM 201. This exemplary embodiment of electrically conductive connector 100 may be useful for making two releasable connections between an electrically conductive connector 100 and two adjacent TEMs. The embodiment of electrically conductive connector 100 shown in FIG. 10 and FIG. 3 may be useful for making a releasable and rotatable connection between first connecting region 101 and first TEM 201a and between second connecting region 102 and second TEM 201b. In the embodiment shown in FIG. 3, electrically conductive connector 100 is configured such that each of the connections to adjacent TEMs 201a and 201b are provided by a plug-receptacle connection. FIG. 3 is a view showing first connecting region 101 that is aligned to be connected with electrical lead 104 of TEM 201a, wherein first connecting region 101 is a receptacle for receiving electrical lead 104 that is a plug. Here, second connecting region 102 is also a receptacle and is shown as being connected to an electrical lead 104 of TEM 201b.

As used herein a plug-receptacle connection is made by a male plug and a female receptacle. A plug-receptacle connection as used in embodiments described herein is a releasable connection and may be a rotatable connection or a non-rotatable connection. One exemplary format of a releasable and non-rotatable plug-receptacle connection uses a flat conductive blade that can be inserted into a flat blade-shaped receptacle.

In some aspects, a plug-receptacle coupling of a connecting region 101 or 102 to TEM 201 allows for rotation about an axis of the receptacle, i.e., the coupling is a rotatable coupling, and the connecting region coupled to a TEM 201 in this manner is said to be rotatably coupled to the TEM. In some embodiments, a rotatable coupling comprises a plug and a receptacle that each have a circular cross section and are substantially cylindrical in shape, and rotation is enabled around the longitudinal axis of the cylindrically shaped plug-receptacle connector, the longitudinal axis being a line through the center of the receptacle and parallel with the plug aspect of the connection. As such, the receptacle extends along a longitudinal axis and has an interior space for receiving a plug. Exemplary cylindrically shaped plug-receptacle connections are shown in FIGS. 1A-1C, FIG. 2, and FIG. 3.

The connection between a plug and a receptacle should be sufficiently tight to provide physical contact for making a good electrical connection. For some embodiments described herein, it is preferred that a plug-receptacle connection has at least one mechanism for enhancing the security of a releasable connection between a connecting region 101, 102 and TEM 201 while maintaining relatively easy releasability of the coupling between the plug and the receptacle, and in some embodiments while still allowing rotatability of the connection. Mechanisms for achieving these requirements are known to a person having ordinary skill in the electrical arts and include by way of example only hyperboloid contacts, any of numerous banana plug configurations that use the concept of spring metal applying outward force to the interior of a receptacle, and spring metal contacts on the interior of the receptacle part of the connection.

It is to be noted that a plug-receptacle connection between a connecting region 101, 102 and TEM 201 may be configured such that the connecting region 101, 102 includes either a plug or a receptacle for making the connection. If the connecting region is configured with a plug, the receptacle is part of the TEM 201 to which the connecting region will be coupled. Similarly, if the connecting region is configured with a receptacle, the plug is part of the TEM 201 to which the connecting region will be coupled. In many embodiments, a plug or receptacle of TEM 201 is part of electrical lead 104 of TEM 201 and connects to a positive or negative terminal of the TEM as in FIG. 2 and FIG. 3. The use of plug-receptacle connections for coupling electrically conductive connector 100 with a TEM 201 enables facile modification of TED 200, such as adding or removing TEMs when it is desirable to make a TED larger or smaller respectively. Similarly, plug-receptacle connections enable facile modification of the shape of a TED for example to enhance conformability of the TED to a surface and contact of the TED with the surface.

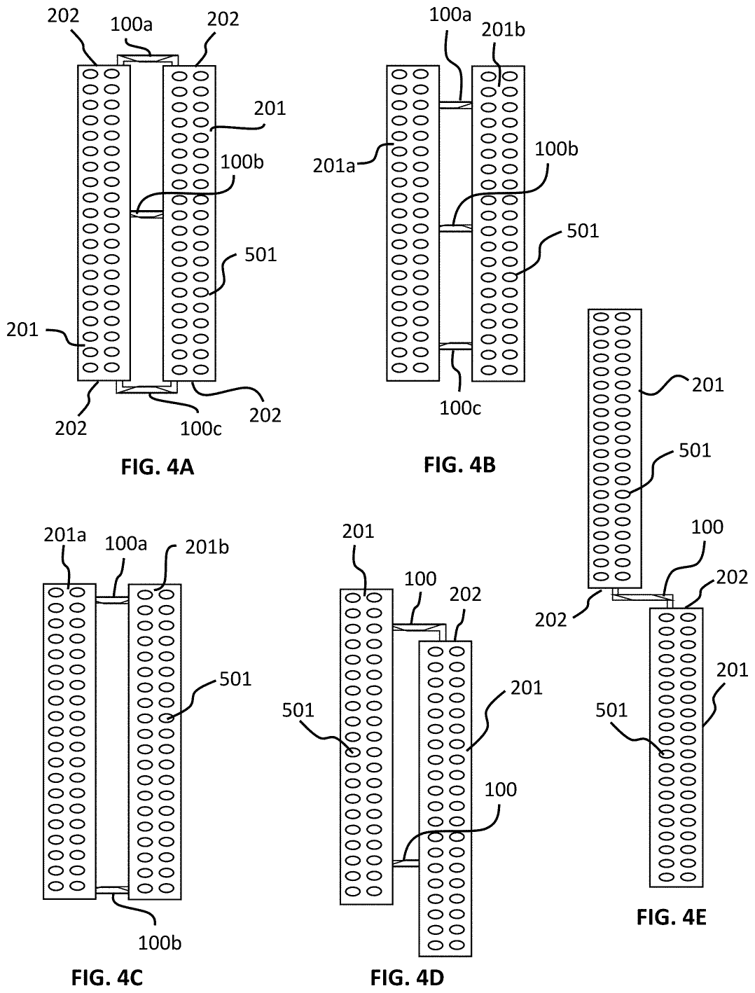

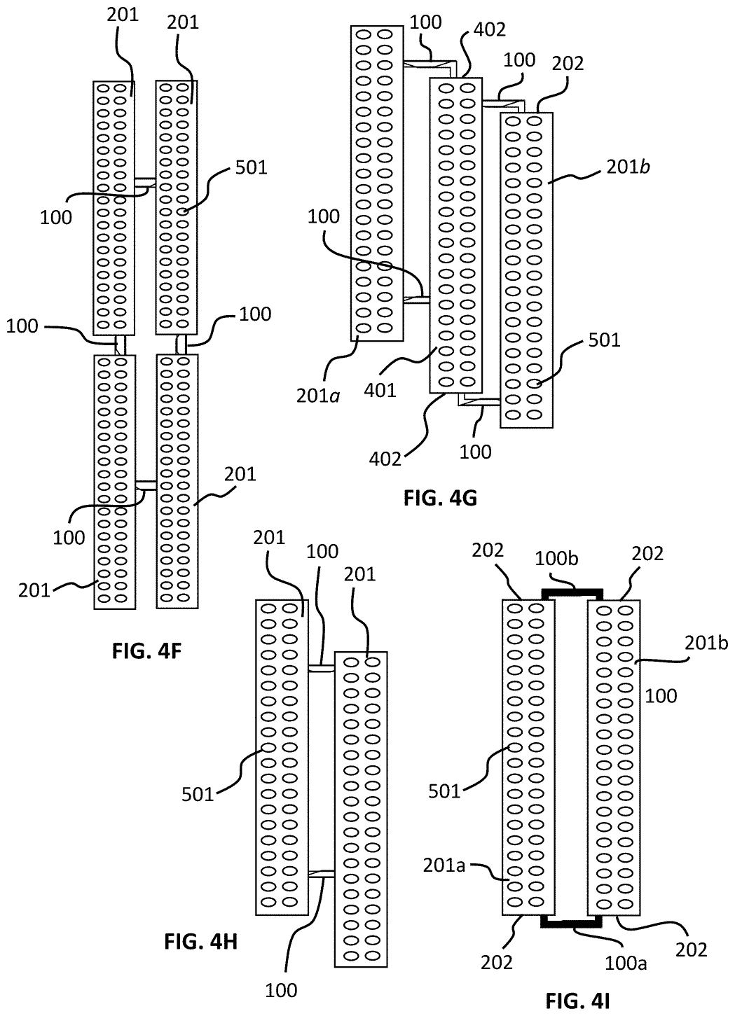

In many embodiments, for electrically and mechanically coupling adjacent TEMs 201, electrically conductive connector 100 is positioned at or near “ends” 202a and 202b of adjacent TEMs 201a and 201b, respectively. That is, electrically conductive connector 100 may be coupled to adjacent TEMs as shown in FIG. 2, in which connector 100 is not positioned between the adjacent TEMs. In some embodiments, connector 100 may be positioned in a location that is between adjacent TEMs 201a and 201b and near ends 202a and 202b, such as for example in the embodiment shown in FIG. 4C. Electrically conductive connector 100 may be positioned at any of a variety of locations along TEMs for connecting adjacent TEMs 201.

FIGS. 4A-4I schematically depict exemplary embodiments for connecting two or more adjacent modules (TEM 201; spacer module 401 in FIG. 4G) with electrically conductive connectors 100. Each combination of TEMs 200, depicted in FIGS. 4A-4I, represents a TED 200. In embodiments shown in FIG. 4A-4H, each electrically conductive connector 100 has at least one of the first and second connecting regions releasably and rotatably coupled to the respective first or second TEM 201 or spacer module 401 in FIG. 4G. As used herein, when “at least one of the first and second connecting regions is releasably and rotatably coupled to the respective first or second TEM”, it means that the first connecting region 101 is releasably and rotatably connected to the first TEM 201, or the second connecting region 102 is releasably and rotatably connected to the second TEM 201, or the first connecting region 101 is releasably and rotatably connected to the first TEM 201 and the second connecting region 102 is releasably and rotatably connected to the second TEM 201.

Mobility of adjacent and connected TEMs 201 relative to each other can be affected by the type of connection between a connecting region 101, 102 and a TEM 201 and by the deformation of elastically deformable region 103. For example, in some aspects it may be preferred that the mobility of connected TEMs 201 relative to each other be affected only by the deformability of deformable region 103. In some aspects, it may be preferred that the mobility of connected TEMs 201 relative to each other be affected partially by the deformability of deformable region 103. In some embodiments, one or more connections between connecting regions 101, 102 and TEMs 201 may preferably be non-rotatable connections. In some aspects, it may be preferred that the movement of connected TEMs relative to each other be affected by both deformability of deformable region 103 and rotatability of one or more connections between connecting regions 101, 102 and TEMs 201. In some embodiments it may be preferred that the one or more connections between regions 101, 102 and TEMs 201 be rotatable connections, which may enhance the movement of adjacent TEMs relative to each other. In some aspects, the extent of movement of connected adjacent TEMs relative to each other can be adjusted by adjusting the type of coupling or connection between a connecting region 101, 102 and the TEM 201 to which the electrically conductive connector 100 is coupled and can be selected based on the specific application for which a TED is employed. In some aspects, adjusting the type of couplings can be useful for adjusting conformability of a TED to a surface and may be useful for improving thermal contact of the TED with the surface. This may be particularly useful with an irregular surface such as for example a body part.

In some embodiments, a TEM 201 connected to a plurality of electrically conductive connectors 100 is non-rotatably connected to each of first 101 and second 102 connecting regions, in each of the plurality of electrically conductive connectors 100. For example, FIG. 41 shows an exemplary embodiment of this arrangement in which all connections between first 101 and second 102 connecting regions of electrically conductive connectors 100a, 100b and TEMs 201a, 201b are non-rotatable. The non-rotatable connections are represented by the black boxes at ends 202 of the modules 201a, 201b. If, as in this example, all connections are non-rotatable connections, the mobility of adjacent TEMs 201a and 201b relative to each other may be affected only by deformation of the elastically deformable regions 103 in electrically conductive connectors 100a and 100b.

In some aspects, for example referring to FIG. 4C, electrically conductive connectors 100a and 100b may both be non-rotatably connected to TEM 201a and rotatably connected by plug-receptacle connections to TEM 201b. In this embodiment, the mobility of adjacent TEMs 201a and 201b relative to each other may be affected by deformation of elastically deformable region 103 in 100a and 100b and by the rotatability of the plug-receptacle connections between 100a and 201b and between 100b and 201b. In some aspects, the non-rotatable connections between 100a and TEM 201 and between 100b and TEM 201 may be non-rotatable connections that are releasable connections. In some aspects, the non-rotatable connections between 100a and TEM 201a and between 100b and TEM 201b may be non-rotatable connections in which the connecting regions are non-releasably, i.e., fixedly, attached to TEM 201 and are thus fixedly attached to TEM 201.

In some embodiments, a TEM 201 connected to a plurality of electrically conductive connectors 100 may be rotatably connected to each of the plurality of connectors by for example a rotatable plug-receptacle connection. For example, referring to FIG. 4B, adjacent TEMs 201a and 201b may be connected by three electrically conductive connectors (100a, 100b, 100c). In some embodiments, 100a, 100b, and 100c may each be rotatably connected by plug-receptacle connections to both TEM 201a and TEM 201b. In some embodiments, the electrically conductive connector 100 shown in FIG. 10 and FIG. 3 can be useful for making this type of connection. In this exemplary embodiment, the rotatability of each plug-receptacle connection and the deformability of elastically deformable region 103 in each of 100a, 100b, and 100c may contribute to the mobility of the adjacent TEMs 201a, 201b relative to each other, thereby enabling improved conformability of a TED with a surface to which it is applied.

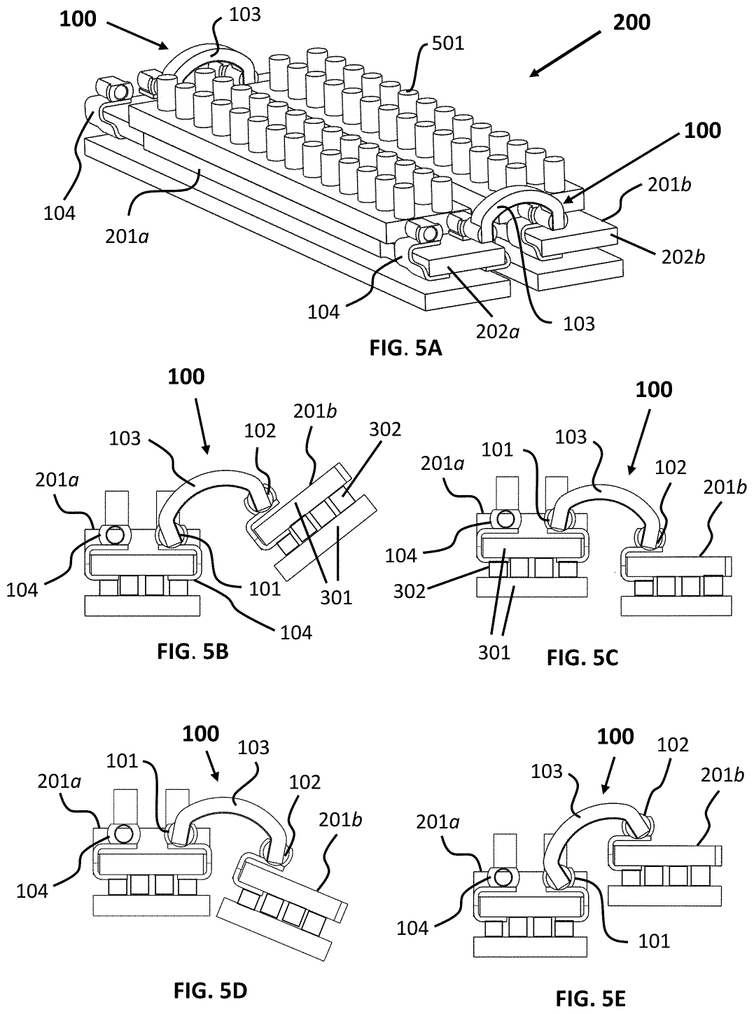

FIGS. 5A-5E are schematic depictions of exemplary embodiments of a TED 200 with rotatable connections between each electrically conductive connector 100 and TEMs 201a, 201b. In these exemplary embodiments, adjacent TEMs 201a, 201b are electrically and mechanically connected by two electrically conductive connectors 100. FIGS. 5B-5E depict exemplary connections at an end of TED 200 having a pair of TEMs as shown in FIG. 5A. In these exemplary embodiments, first connecting region 101 (FIGS. 5B-5E) is rotatably connected to TEM 201a near end 202a (FIG. 5A) and second connecting region 102 is rotatably connected to TEM 201b near end 202b (FIG. 5A). FIGS. 5B-5E also show exemplary movements of TEMs 201a and 201b relative to each other that are possible in this exemplary embodiment of a TED. In some aspects, a TEM 201 may rotate over a range of about 180 degrees, e.g., about plus or minus 90 degrees in relation to an adjacent TEM 201, thereby enabling and enhancing conformability of a TED 200 having multiple TEMs 201 to surfaces having right angles or approximately right angles.

In some embodiments, one or more TEMs 201 may be made of conventional materials, wherein TEEs 302 are positioned between thermally conductive substrates 301 that are conventional ceramic plates. However, in some aspects non-ceramic materials may be used for a TED 200 such as a TEM 201. In many aspects, TEEs 302 may be positioned between thermally conductive substrates 301 that are high thermal conductivity printed circuit boards (PCBs), such as by way of example only, metal core PCBs. Metal core PCBs often replace a majority of the epoxy fiberglass of traditional electronics boards (FR4) with thin, lightweight metal films that reduce mass and increase thermal conductivity, making them especially advantageous for some applications. Metal core PCBs are commercially available (e.g., San Francisco Circuits, Inc., San Mateo, Ca.) and can be used for manufacturing TEMs 200 having custom configurations. In some embodiments, T-Preg™ HTD (Laird Technologies, Chesterfield, Mo.) may be used in conjunction with copper foil and an integral metal plate to provide a circuit board laminate that has superior thermal management capabilities. In some embodiments, both thermally conductive substrates 301 may comprise thin copper foil laminated to an insulating T-preg layer forming a low-profile, thin thermally conductive substrate and corresponding TED 200. TED 200 depicted in FIG. 5A is an example of a TED 200 comprising TEMs 201a and 201b that have metal core PCB thermally conductive substrates 301. In some embodiments, TEM 201 may further comprise one or more heat dissipation structure 501. For example, a TEM 201 that is a metal core PCB may comprise heat dissipation structures 501, which in some aspects may also be referred to herein as fins, for increasing the rate of heat transfer from the module 201 by increasing convection. In some embodiments, heat dissipation structures 501 may be one or more than one of skived fins, extruded fins, or pin fins or one or more other structures of any shape or size that is capable of dissipating heat and is compatible with the TED application, e.g., cylindrical, rectangular prism, cuboid, trapezoidal, conical, elliptical, and irregularly shaped, to name a few. Other configurations of heat sinks that may be useful for heat dissipation structures 501 are known to persons having ordinary skill in the art. In some aspects, heat exchange can be improved by increasing the heat transfer surface area of fins. In FIGS. 5B-5E, only module 201a is depicted as being modified with heat dissipating fins 501.

A TEM 201 may have any of a variety of shapes and sizes. In many embodiments, TEM 201 has a rectangular shape and may be elongated or may be a substantially square shape. In some embodiments, TEM 201 may be circular, elliptical, another regular geometrical shape, or an irregular shape. The foregoing are only exemplary shapes. A TEM 201 can be custom manufactured to have any desired shape, which may be selected based on specific needs for a given application.

In some embodiments, adjacent TEMs 201 may be electrically and mechanically connected by at least one electrically conductive connector 100, positioned at any of a variety of locations on the connected TEMs. FIG. 4D depicts an embodiment wherein two adjacent TEMS 201 are connected by two electrically conductive connectors 100 positioned at different locations between TEMs 200. FIG. 4E depicts an embodiment wherein two adjacent TEMS 201 are connected by one electrically conductive connector 100 at ends 202 of TEMs 201. In some embodiments, adjacent TEMs 201 may be electrically and mechanically connected by a plurality of electrically conductive connectors 100, positioned at any of a variety of locations on a TEM 201. In some aspects, a plurality of TEMs 201 in a TED may be connected to multiple other TEMs 201 by electrically conductive connectors 100. FIG. 4F is an exemplary embodiment of a TED 200 having four TEMs 201, each TEM 201 being connected to two adjacent TEMs 201 as shown. Each TEM 201 in FIG. 4F is connected to an adjacent TEM 201 by a single electrically conductive connector 100. TEDs 200 may be made to be conformable to complex three dimensional surfaces or structures by adjusting or modifying one or more of TEM 201 shape, size, and number, the shape and/or type of electrically conductive connector 100, the deformability of elastically deformable region 103, the relative movement of adjacent TEMs 201, and the rotatability or non-rotatability of couplings between TEMs 201 and electrically conductive connector 100, to name a few exemplary approaches. In some aspects, the number of electrically conductive connectors 100 connecting adjacent TEMs 201, can be selected to facilitate conformability of a TED 200 to a complex three dimensional surface or structure.

In some embodiments, a TED 200 can comprise one or more “spacer module” 401 (FIG. 4G) that may lack TEEs 302 yet have electrical leads for pass-through electrical connection between TEMs, e.g., between TEMs 201a and 201b, or between a TEM 201 and a power source 901. Electrically conductive connector 100 may also be useful for connecting a spacer module 401 with a TEM 201 or for connecting adjacent spacer modules 401. Like a TEM 201, spacer module 401 may be rotatably or non-rotatably coupled and releasably or non-releasably (fixedly) coupled to electrically conductive connector 100 and can have mobility characteristics equivalent to those of a TEM 201. In some aspects, a spacer module 401 may be electrically and mechanically connected to an adjacent TEM 201 or to an adjacent spacer module 401 by multiple electrically conductive connectors 100, positioned at any of a variety of locations on the adjacent modules. The exemplary embodiment depicted in FIG. 4G shows spacer module 401 connected to adjacent TEMs 201a, 201b with electrically conductive connectors 100 being connected to space module 401 at each of spacer module ends 402. Additional electrically conductive connectors 100, not positioned at ends 402, also serve to connect spacer module 401 with TEMs 201a, 201b.

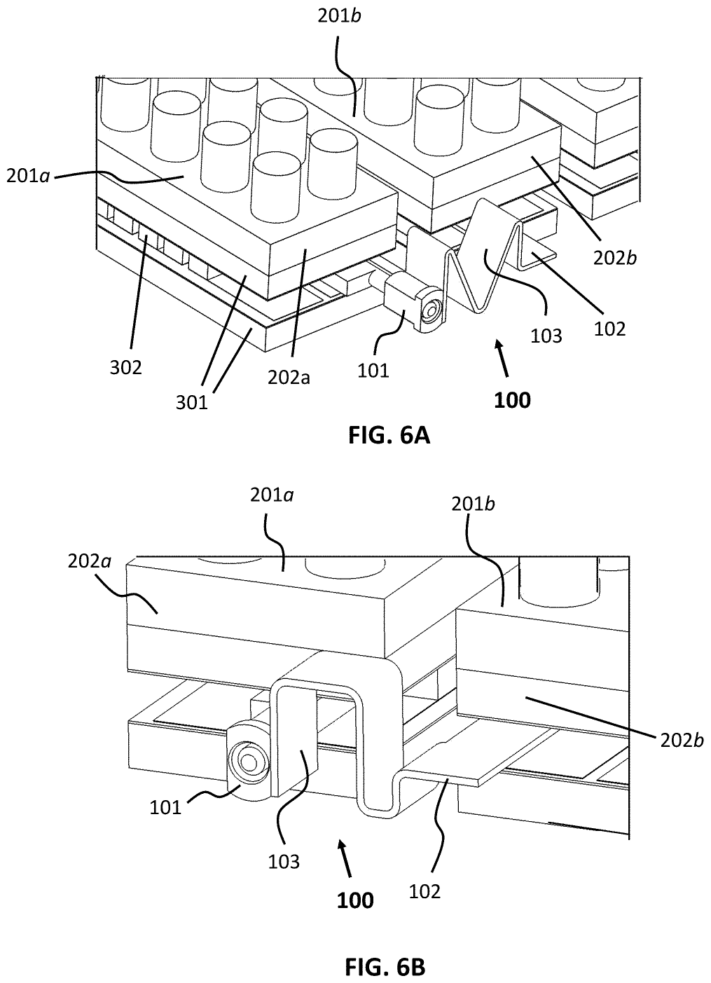

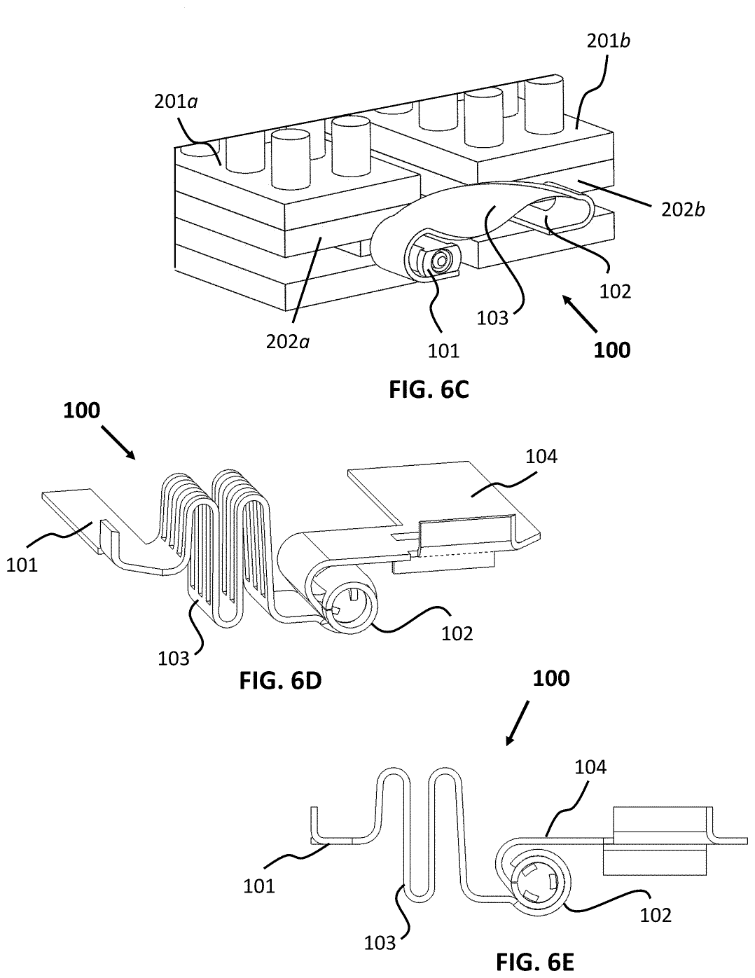

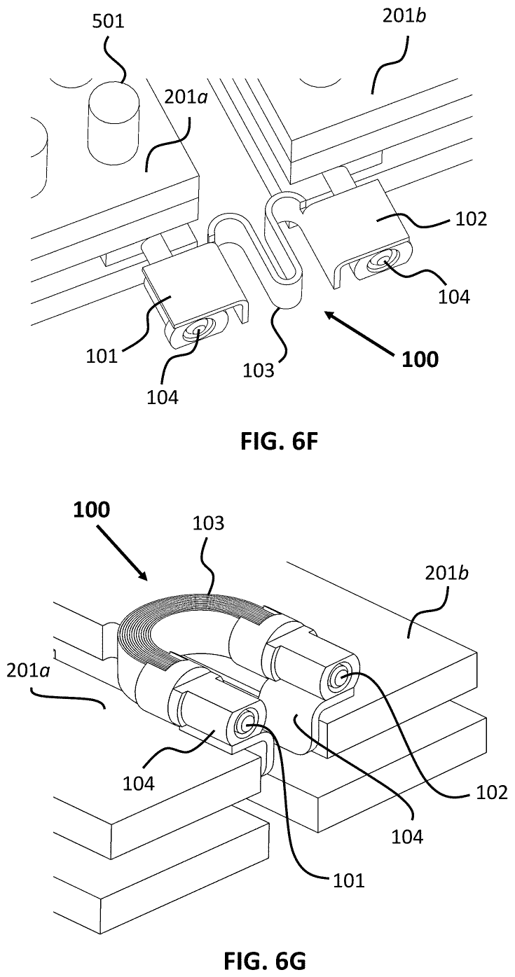

FIGS. 6A-6G show exemplary embodiments of electrically conductive connector 100. In each exemplary embodiment, electrically conductive connector 100 is a compliant mechanism comprising a first connecting region 101 for coupling to a first thermoelectric module 201a, a second connecting region 102 for coupling to a second thermoelectric module 201b, and an elastically deformable region 103 between first connecting region 101 and second connecting region 102, wherein at least one of the first 101 and second 102 connecting regions is configured for releasable and rotatable coupling to a respective first 201a or second 201b TEM. FIG. 6E is an end view of the embodiment depicted in FIG. 6D. FIGS. 6F and 6G show exemplary embodiments of electrically conductive connector 100, wherein both first connecting region 101 and second connecting region 102 are configured for releasable and rotatable coupling to respective TEMs 201a and 201b. Electrically conductive connector 100 depicted in FIG. 6F, comprises connecting regions 101 and 102, each being a flat blade having an integrated receptacle for establishing a releaseable, rotatable connection with electrical lead 104 that is configured as a plug. For the electrically conductive connector 100 depicted in FIG. 6G, connecting regions 101 and 102 are each configured as a plug for establishing a releaseable, rotatable connection with electrical lead 104 from TEMs 201. In this embodiment, electrical leads 104 are configured as flat blades having an integrated receptacle, for establishing a releaseable, rotatable connection with connecting regions 101, 102.

Elastically deformable region 103 may have any of a variety of shapes and configurations, which in some aspects, may be selected according to the application for a TED 200. Some exemplary shapes are shown in FIGS. 1A-1C, FIG. 2, and FIGS. 6A-6G. In many embodiments, elastically deformable region 103 is a region of metal that is curved when in a non-deformed position. A curved elastically deformable region 103 may have a single slight curve as the exemplary embodiments in FIGS. 1B, 10, and 6C. In some embodiments, elastically deformable region 103 may be a region of metal that has one or a plurality of relatively sharply curved regions or “bends”, such as for example in the embodiments shown in FIGS. 6A, 6B, and 6D. As used herein a bend refers to a relatively sharp curve in a structure. In some embodiments, elastically deformable region 103 may have one or more than one curves or bends similar to those in the letters C, S, U, M, N, V, W, and Z. In some embodiments, elastically deformable region 103 may comprise a twist or other conformation as in FIG. 6C. It will be understood that the shape of elastically deformable region 103 is not limited to the examples listed here. The number of bends, curves, twists, and/or other conformations in elastically deformable region 103 may be selected based on any of a variety of reasons including but not limited to the application of a TED 200.

In some aspects, elastically deformable region 103 need not be a continuous piece of solid metal. For example the electrically deformable region 103 in the exemplary embodiment shown in FIG. 10 and FIG. 3 has voids that run parallel to the length of the region. One or more voids that may be present in elastically deformable region may take any of a variety of shapes, which may be chosen to adjust deformability of elastically deformable region 103 as desired. Voids may be, by way of example only, square, rectangular, circular, elliptical, triangular or other geometrical shape.

In embodiments described herein, electrically conductive connector 100 is made of electrically conductive metal or metal alloy. It is preferred that the metal be an elastically resilient material so that elastically deformable region 103 can be configured to elastically deform under an applied force or stress to the extent that under normal use the material returns spontaneously to its original form after the force causing the deformation is removed. Some examples of useful metals and metal alloys that can meet these requirements include gold, silver, nickel, copper, tin, aluminum and alloys of these. Elastically deformable region 103 need not comprise a single piece of metal. For example, in the embodiment of FIG. 6G elastically deformable region 103 comprises a leaf-spring type mechanism having a plurality of flat pieces of metal arranged as layers.

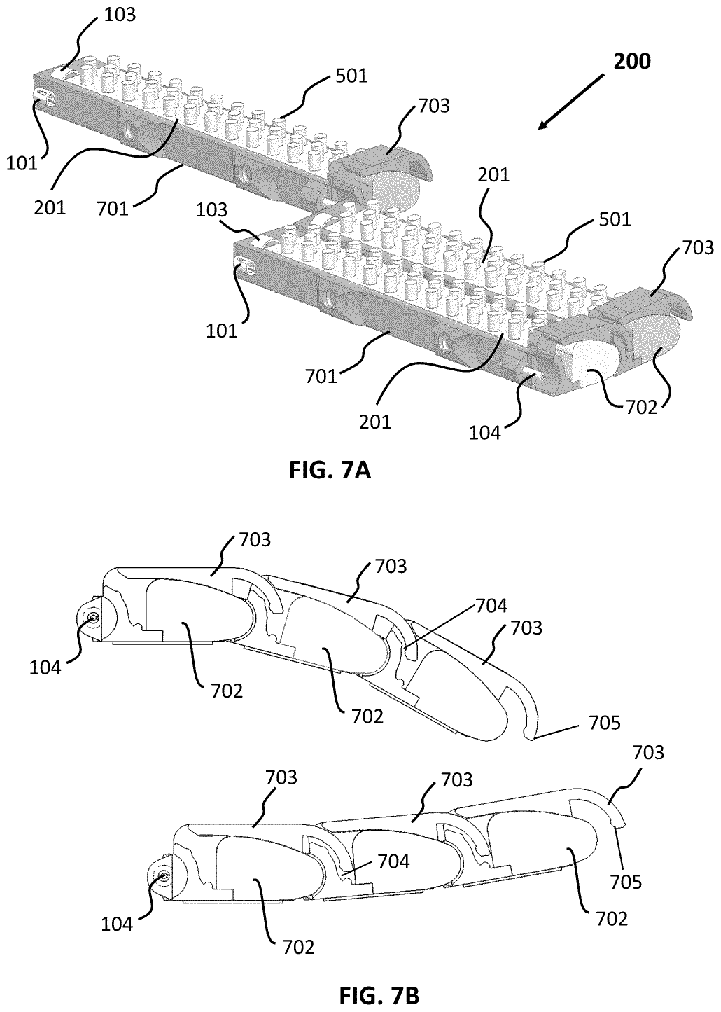

FIGS. 7A-7B show embodiments of a carrier frame 701 and associated structures. In some embodiments, as shown in FIG. 7A, a TED 200 such as a TEM 201 may be positioned in a carrier frame 701, which in some aspects is a rigid plastic structure. Carrier frame 701 may be useful for connecting adjacent TEMs 201 and/or spacer modules 401, may enable or assist with rotatable connection of adjacent modules for facilitating movement of one module 201 or 401 relative to an adjacent module, and can facilitate TED 200 assembly. In some aspects, a carrier frame 701 may be used to provide a path for heat exchange fluid flow around a TED to enhance cooling or heating of a surface.

A carrier frame 701 can be useful for protecting selected parts of a TED 200 while leaving heat dissipation structures 501 accessible to the surrounding environment. In some embodiments, a portion of electrically conductive connector 100 that connects adjacent TEMs 201 may be positioned in a carrier frame. This exemplary embodiment is apparent in FIG. 7A, where elastically deformable region 103 is positioned within carrier frame 701 and connecting region 101 is positioned outside of carrier frame 701 for making electrical connection with an adjacent TEM 201. Carrier frame 701 may also be configured to facilitate soldering or other method for fixedly attaching one or more of first 101 and second 102 connecting regions to a TEM 201. In some embodiments, electrically conductive connector 100 may be enclosed or partially enclosed by a protective cover 702, which can be made of a soft or hard plastic or other material, by way of example only. Carrier frame 701 and protective cover 702 can be useful for providing protection for TEEs 302, TEMs 201, and electrically conductive connectors 100 against breakage or against liquid by providing for example a water-tight seal.

In some embodiments, carrier frame 701 may be configured for enabling control over movement of a TEM 201 in relation to an adjacent TEM 201. An exemplary embodiment of a movement control mechanism 703 is shown in FIGS. 7A-7B. Movement control mechanism 703 may be used, by way of example only, for controlling movement of a TEM 201 that is rotatably coupled to an electrically conductive connector 100 or to an adjacent TEM 201 and/or for controlling deformation of elastically deformable region 103. Movement control mechanism 703 may be part of or attached to carrier frame 701 or may be a stand-alone piece and can be made of, by way of example only, soft plastic, rigid plastic, or a combination of the two, or another material. Movement control mechanism 703 may be shaped so as to have regions or features that are positioned and shaped to contribute to movement control. Exemplary features may include notches 704 that may function with arm 705. The foregoing serve only as examples. Movement control mechanism 703 may take any of a variety of shapes and have variously shaped features useful for contributing to movement control of adjacent modules which may be TEMs 201 and/or spacer modules 401. In some aspects then, TED 200 may have at least one TEM 201 in a plurality of electrically connected TEMs 201 that is positioned in a carrier frame 701, and carrier frame 701 may be configured for controlling movement of TEMs 201 and/or spacer modules 401 relative to one another.

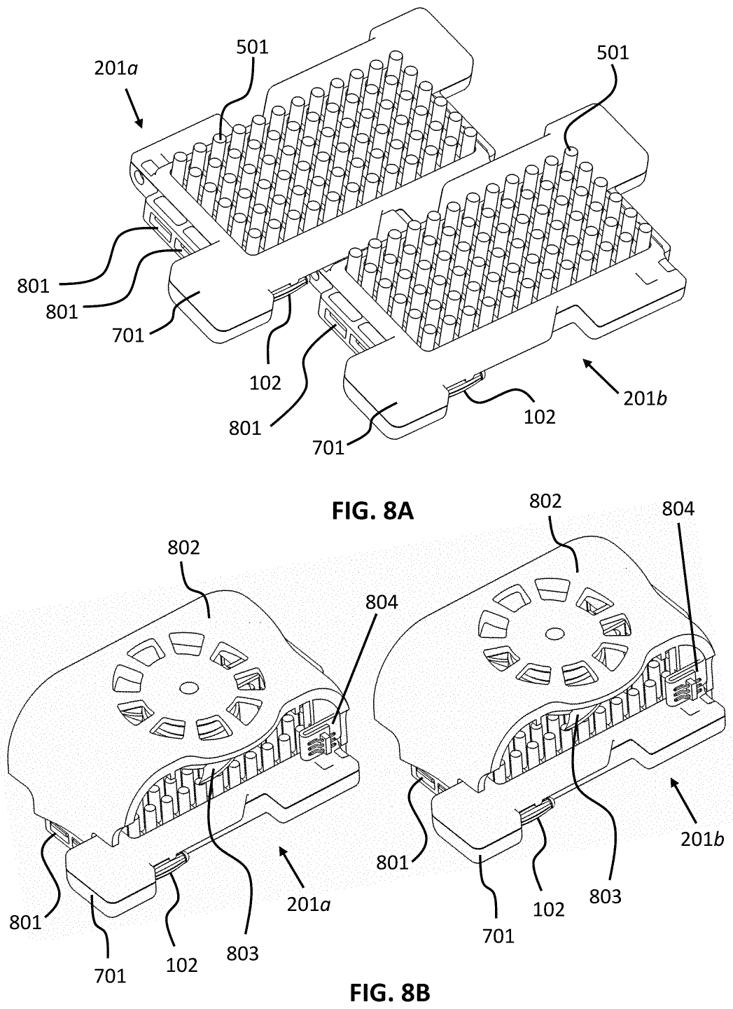

FIGS. 8A-8B illustrate embodiments of TEMs 201 positioned in carrier frame 701. In this exemplary embodiment, TEMs 201a, 201b are rectangular in shape and are each positioned in a carrier frame 701. Each module further comprises heat dissipation structures 501. In this aspect, carrier frame 701 comprises seating sockets 801 than can be used for securing fan housing 802 or another type of housing. Here, conductive compliant connector 100 is largely enclosed in carrier frame 701. Connecting region 102 is exposed to facilitate the connection of TEMs 201a, 201b to each other. In some aspects, a TED 200 such as a TEM 201 may comprise a fan 803 that may be positioned on a hot side 1002 or cold side 1001 of a TEM 201. As shown in FIG. 8B, fan 803 is positioned within fan housing 802, fan housing 802 being secured to carrier frame 701 via one or more seating socket 801. In this exemplary aspect, fan 803 is positioned on a hot side 1002 of TEM 201 and is configured for blowing hot air from heat dissipation structures 501 to enhance efficiency of heat removal from TEM 201. Fan connector 804, which in some aspects may be a flex circuit, is configured to connect fan 803 to power source 901.

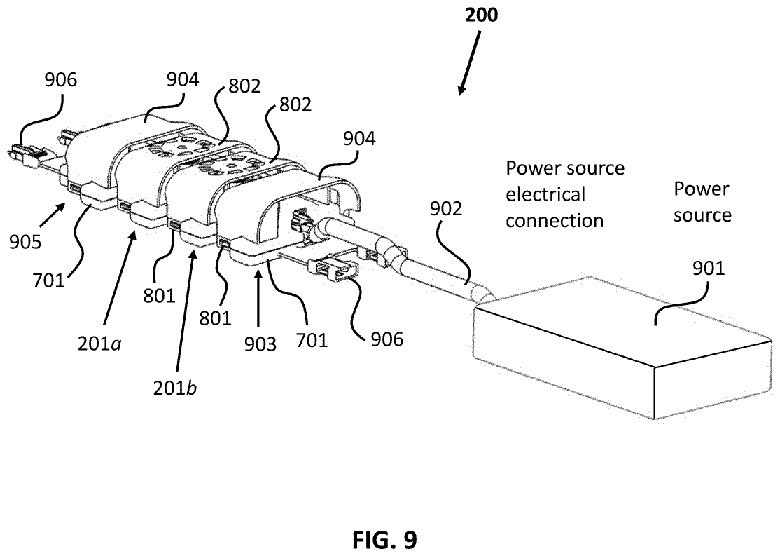

FIG. 9 schematically illustrates an exemplary embodiment of a TED 200. In this embodiment, power source 901 is electrically connected by electrical connection 902 to power receiving module 903. Power receiving module 903 is configured to receive and transfer electrical power to TEMs 201a, 201b. Power return module 905 functions as a terminal module configured for returning electrical connection and power back through TEMs 201a, 201b. In this aspect, power receiving module 903 and power return module 905 are each enclosed in a carrier frame 701 and protected by a module housing 904 that is secured to carrier frame 701 at seating sockets 801. Housings, e.g., 802, 904 may be useful for protecting component parts of a TEM 200 and can be of any suitable size, shape, or material that is compatible with attachment to a TEM 200. For example only, housings 802, 904 may be made of soft plastic, rigid plastic, or a combination of the two, or another material or combination of materials.

In some embodiments, such as depicted here, TED 200 may comprise a fastener 906, such as the mechanical buckle depicted in this exemplary embodiment. In some aspects, fastener 906 can be useful for securing TED 200 to a surface or object that is to be cooled or heated. Securing a TED 200 to a surface or object with fastener 906 may functionally assist with maintaining contact between the TED 200 and the surface or object that is being heated or cooled. Components of fastener 906 may be attached to any number of selected elements of TED 200. By way of example only, fastener 906 may be attached to carrier frame 701 and/or power source 901. Fasteners 906 are not limited to the mechanical buckle format depicted in FIG. 9. By way of example only, other useful fasteners may include hook and loop fasteners, straps, belts, elastic bands, and adhesive tapes to name only a few. In many embodiments, the type of fastener 906 selected for use with a TED 200 may be chosen based on its ability to enhance contact between an irregularly shaped surface or structure and the TEMs 201 in the device.

In many embodiments, a TED having a plurality of electrically and mechanically connected TEMs 201 will be connected to a processor such as an electrical controller board for regulating power input from a connected power source 901, which in many aspects may be a battery for example. In some aspects, power source 901 may be connected to two separate groups of electrically and mechanically connected TEMs 201 through separate controller boards positioned between the battery and the respective group of TEMs 201. In some aspects a main controller board may be positioned between a power source 901 (e.g. a battery) and one or more controller board/TEM assembly. A controller board processor may be useful, by way of example only, for adjusting the target temperature of a cold side 1001 of a TED 200 that is a TEC, for providing surge protection to a TED 200, for regulating one or more cold side 1001 and/or hot side 1002 fans of a TED 200, and for controlling fluid flow through a TED 200. By way of example, a controller board may be used to control current flow to fan 803 that is configured to blow heat from heat dissipation structures such as fins 501, as depicted in FIG. 8B. In some aspects a controller may regulate temperature by regulating power input through sensors embedded in one or more TEMs 201. A processor or controller board may be positioned in any of a variety of locations, including for example in power receiving module 903, power return module 905, and/or in one or more TEMs 201, or at another location that allows for regulating power input from power source 901. In some aspects, one or more TEM 201, power receiving module 903, and/or power return module 904 may be configured for wireless communication with a controller.

Rotatable coupling of TEMs 201 and elastic deformation of electrically conductive connector 100 may be used to enable and enhance the conformability of a TED 200 to an irregularly shaped, circular, or non-planar surface or structure. FIGS. 10A-10B depict the TED 200 of FIG. 9 in curved conformations that can be useful in thermoelectric applications that require the positioning of TED 200 against a curved surface or structure. Power source 901 is not shown in FIGS. 10A-10B.

In cooling applications, one side of a TEM 201 may be positioned against a hot object or surface that is to be cooled and is referred to as the cold side 1001 of TEM 201. During cooling, heat pumped from the hot object or surface positioned on cold side 1001 of TEM 201 is transferred from cold side 1001 (FIG. 10B) and through TEM 201 to the opposing side, also referred to as the hot side 1002 of TEM 201. As described for FIGS. 8A-8B, in some aspects, heat dissipation structures 501 and one or more fan 803 may be affixed to hot side 1002 of TEM 201, as shown in FIG. 10A, to assist in heat removal.

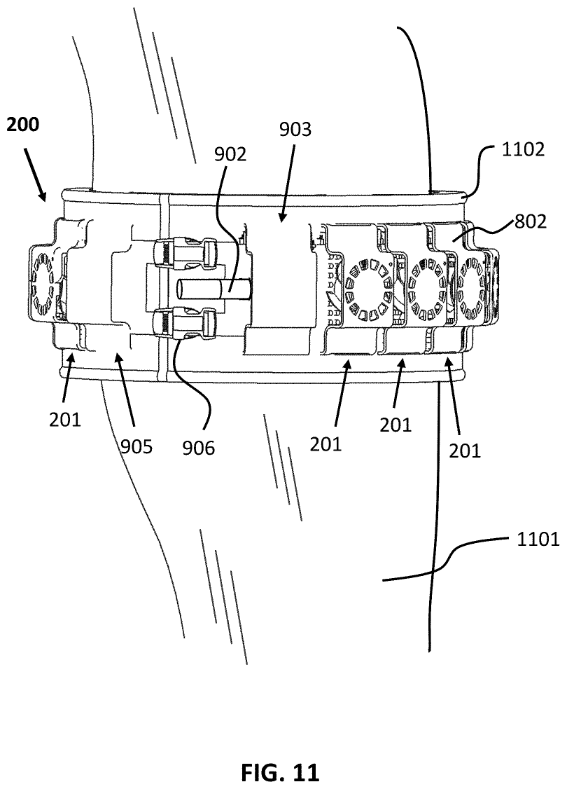

FIG. 11 schematically depicts an embodiment of a TED 200 affixed to a body part 1101 (e.g., an arm, a leg, or another body part). In this embodiment, TED 200 comprises a plurality of TEMs 201 positioned in a fabric cuff 1102 and electrical connection 902 for electrically connecting power source 901 (not shown here) to power receiving module 903. TED 200 also comprises power return module 905. The device may be affixed to body part 1101 with fastener 906, here a mechanical buckle. Conductive compliant connectors 100 connecting adjacent TEMs 201 in this exemplary TED 200 may be designed to improve conformability of a thermoelectric device with an irregularly or non-uniformly shaped surface such as the surface of body part and/or to enhance contact between cold side 1001 surfaces and the irregularly shaped surface so as to improve efficiency of thermoelectric cooling.

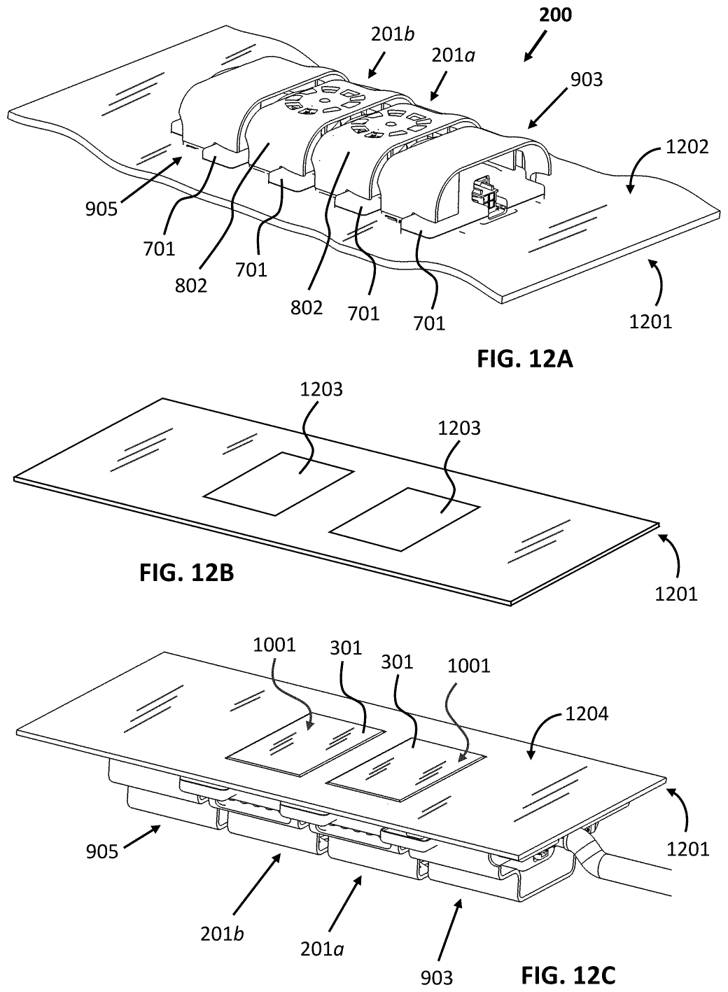

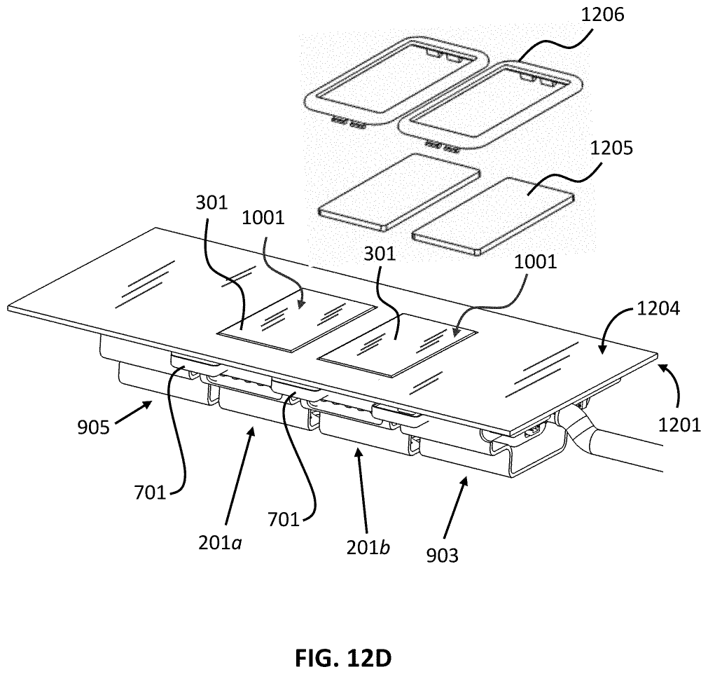

TEDs 200 described herein can be useful in a wide variety of applications. Uses include incorporating a TED 200 in an article of apparel or a bandage that can be worn or applied to a human or animal body for heating or cooling the body or a body part 1101. For example, a TED 200 incorporated in apparel or a bandage can be useful for treating an injury, for cooling of a cast, for emergency cooling (e.g., a cooling vest for induced hypothermia), or for comfort. As used herein, and by way of example only, apparel includes clothing, shoes, belts, jackets, vests, day wear, night wear, work wear, swim wear, sleep wear, personal protective wear, sports uniforms, professional uniforms, and the like. An article of apparel may be made of a woven fabric such as a textile or a non-woven fabric or another useful material. Methods for incorporating a TED 200 into an article of apparel, include by way of example only, adhesively attaching the TED 200 to the article, releasably attaching the TED 200 to the article such as for example with hook and loop fasteners, and embedding the TED 200 in the article (e.g., by sewing or other means to position the device between layers of fabric). In some aspects, a TED 200 described herein may be incorporated in, attached to, or positioned in a fabric, a material, or a structure that is not designed for use as apparel, using the same or similar methods described above. For purposes of description herein, a material, article, fabric, structure and the like that can incorporate a TED 200 or that a TED 200 may be affixed to in one or more these manners is referred to as a “substrate material” 1201 (FIGS. 12A-12C). In some aspects, it may be preferable that substrate material 1201 having an incorporated TED 200 be relatively flexible and conformable itself so as to provide for facile movement and positioning of TEMs 201 during use of a TED 200 with an irregularly or non-uniformly shaped surface or object. In some aspects, it may be preferable that a substrate material 1201 have limited or minimal flexibility.

FIGS. 12A-12D depict embodiments in which carrier frame 701 is used to incorporate TED 200 with substrate material 1201. In some embodiments, TED 200 that is incorporated with a substrate material 1201 may be affixed to the substrate material 1201 by any of a variety of means including for example by stitching or by fasteners such as screws, brads, hook and loop, adhesives, and snap-together assemblies to name only a few examples. The exemplary embodiments in FIGS. 12A-12C demonstrate the use of carrier frames 701 for incorporating a TED 200 with a substrate material 1201. In this example, TEMs 201a, 201b, power receiving module 903 and power return module 905 are assembled into TED 200 using carrier frames 701. Each TEM 201 comprises fan 803, heat dissipation structures 501, electrical connections, and electrically conductive connector 100 positioned beneath fan housing 802 (as in FIGS. 8A-8B) and positioned at a first side 1202 of substrate material 1201. Substrate material 1201 comprises voids 1203 (FIG. 12B). Using any of a variety of fastening means (e.g., screws, brads, stitching, adhesives to name a few), carrier frames 701 can be mechanically secured to substrate material 1201 at the edges of voids 1203. In this manner, thermally conductive substrate 301 is an exposed surface at cold side 1001 and is exposed at second side 1204 of substrate material 1201. A secure leak proof connection of carrier frames 701 to substrate material 1201 at the edges of voids 1203 can prevent unwanted exchange of hot or cold air across substrate material 1201. In other exemplary embodiments, one or more of carrier frame 701, protective cover 702, fan housing 802, and module housing 904 may be individually or collectively secured to substrate material 1201 for incorporating TED 200 with the substrate material 1201. In some aspects, TED 200 may comprise at least one TEM 201 that is positioned in a carrier frame 701 attached to substrate material 1201.

In some embodiments (FIG. 12D), to assist with efficiency of heat transfer a thermal interface material 1205 may be positioned adjacent to and in contact with thermally conductive substrate 301 that is an exposed surface at cold side 1001 of TEM 201. Thermal interface material 1205 may be, by way of example only, a thermally conductive fabric, gel, liquid, ceramic filler (e.g., boron nitride), adhesive, or phase change material. In some aspects, thermal interface material 1205 may be secured in place with adapter 1206, which may be configured for snap attachment to carrier frame 701.

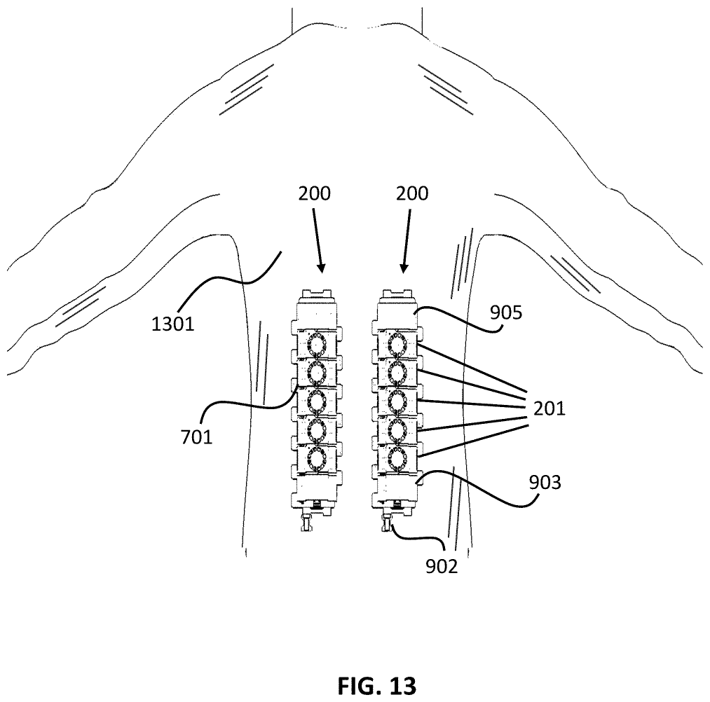

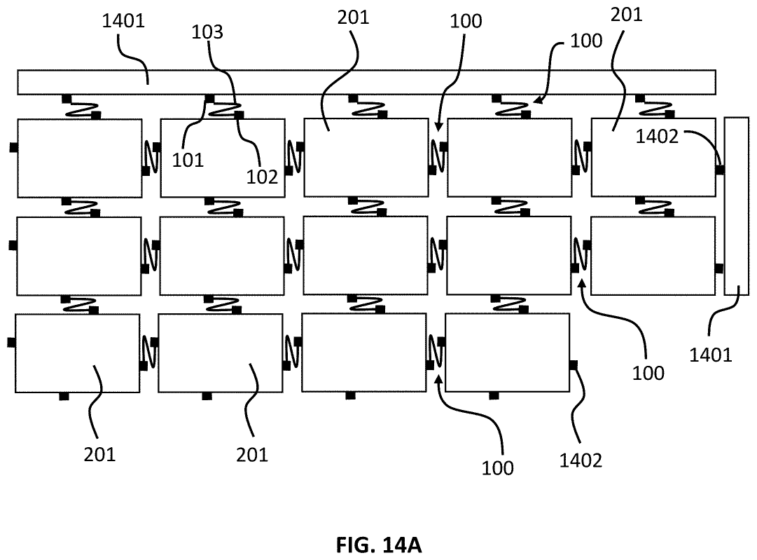

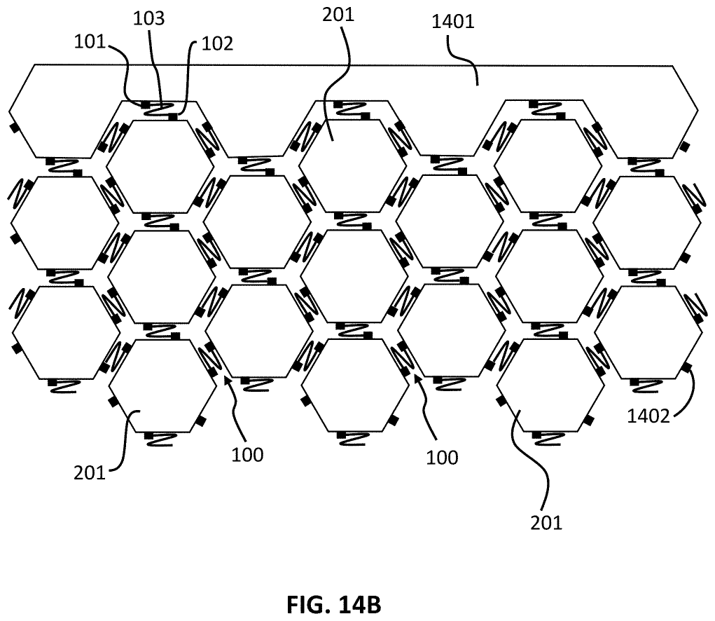

FIG. 13 shows an exemplary embodiment of an article of apparel fitted with two TEDs 200. In this embodiment, jacket 1301 is fitted with two TEDs 200, each TED 200 comprising five TEMs 201 disposed in carrier frames 701, a power receiving module 903, a power return module 905, and electrical connection 902 for connecting to power source 901 (not shown here). As in FIGS. 8A-8B each TEM 201 is configured with a fan 803 and fan housing 802. Here cold side surfaces 1001 of TEMs 201 may be exposed at the “interior” side of jacket 1301 by way of secure leak proof connection of carrier frames 701 to jacket material 1201 at the edges of voids 1203, as described above for FIGS. 12A-12C. This type of embodiment may be useful for cooling an individual's body in high heat situations that require wearing protective gear like a heavy flame-retardant jacket 1301. In some applications, apparel items outfitted with TEDs 200 that utilize electrically conductive connectors 100 having an elastically deformable region 103, can allow for a wide range of body movement while maintaining effective TED 200 performance.

Other examples for using embodiments of TEDs 200 described herein include heating or cooling of body parts such as for treatment of an injury, for cooling of a cast, for emergency cooling (e.g., a cooling vest for induced hypothermia), and for comfort. Exemplary objects for which TEDs described herein may be used for heating and cooling include by way of example only, automotive seats, beverage containers, mattresses, personal protective equipment (PPE), food serving trays, furniture (e.g. chairs and beds), wall strips (e.g., for cooling local regions), and industrial manufacturing tools which require precise temperature control. In some embodiments, a TED 200 can be attached to a body part 1101 or object with a fastener 906 by strapping (e.g., with a belt) or with an elastic band, a hook and loop fastener, adhesive tape or any suitable device or material that can be useful for holding one object or surface in close contact with another object or surface.

In some aspects, TEDs 200 described herein can be useful for generating electricity from waste heat derived for example from heat pipes, exhaust structures, drains or other industrial objects. TEDs 200 described herein can be useful for generating energy such as for use in generating power for spacecraft and for applications in cold environments such as for space probes and deep ocean exploration vehicles and housing. Applications for devices described herein include thermal energy scavenging in conjunction with renewable energy collection such as photovoltaics, solar thermal, wind, nuclear, and isotopic decay.

In some embodiments, TEDs 200 described herein may also be useful when incorporated in or affixed to a surface or structure that is not flexible or that has limited or minimal flexibility. By way of example only, TED 200 having TEMs 201 connected with one or more electrically conductive connectors 100, may be affixed to a metal plate, such as an aluminum plate that can be pre-made with a curved shape. Such a TED 200 may be useful for enabling or enhancing conformability of the thin metal plate to a curved surface for transferring heat to or from the surface.

FIGS. 14A-14B are schematic representations of exemplary arrangements of TEMs 201 connected in two dimensions by electrically conductive connectors 100. FIG. 14A shows an exemplary embodiment for connecting rectangularly shaped TEMs 201 with electrically conductive connectors 100 in two dimensions. Rectangular TEMs 201 arranged in a two-dimensional array may also be shaped as squares. FIG. 14B shows an exemplary embodiment for connecting hexagonally shaped TEMs 201 with electrically conductive connectors 100 in two dimensions. In many embodiments of TED 200 described herein, TEMs 201 may be positioned in any of a variety of different patterns to enable facile positioning of TEMs 201 for a selected level of conformability to an irregularly shaped or non-planar surface. As described previously herein, one or more electrically conductive connectors 100 can be positioned as necessary on at least one side of a TEM 201 and configured with selected types of electrical connectors 101, 102 for electrical and mechanical connection to one or more selected adjacent TEMs 201. In some aspects, a TED 200 comprising TEMs 201 assembled in a two dimensional array may comprise one or more terminal edge connector 1401 for terminating electrical conductivity from TEMs 201 at the edge of a group or array of TEMs 200. In some aspects, one or more terminal edge connector 1401 may be positioned and configured to connect with as many TEMs 201 positioned at the edge of a group of TEMs 201 as is desired. In some embodiments, terminal edge connectors 1401 may be positioned and configured to connect with every TEM 201 positioned at the edge of a group of TEMs 201. In some aspects, one or more electrically conductive connector 100 positioned to connect terminal edge connector 1401 with an adjacent TEM 201 may be configured so as not to be electrically conducting, i.e., connector 100 may be shaped and configured as described elsewhere in the specification with first connecting region 101, second connecting region 102, and elastically deformable region 103 but without establishing an electrical connection between terminal edge connector 1401 and an adjacent TEM 201. In some aspects then, electrically conductive connector 100 may serve to provide only a mechanical connection between terminal edge connector 1401 and an adjacent TEM 201. In some aspects, a conventional electrical connector 1402 lacking an elastically deformable region 103 may be used for connecting TEM 201 to terminal edge connector 1401. In some embodiments, terminal edge connector 1401 may be configured to function as a power return module 905.

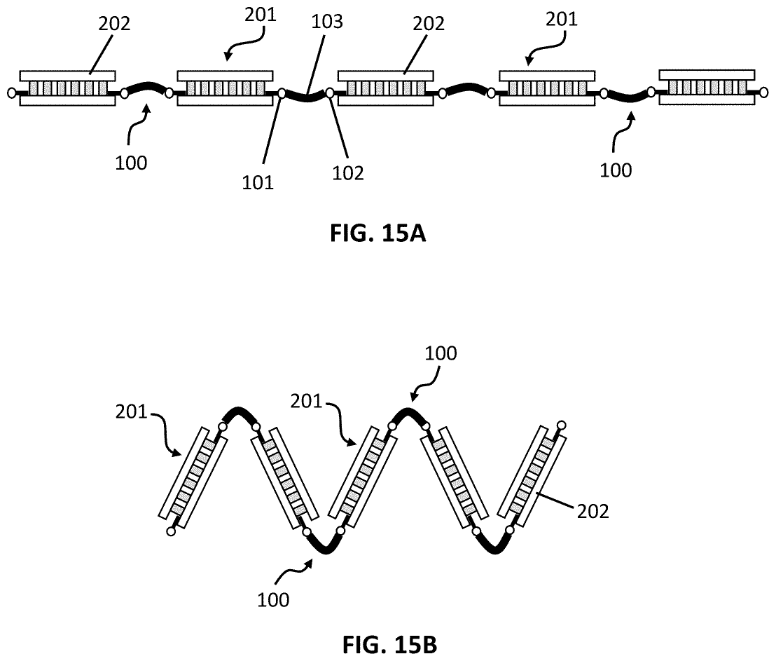

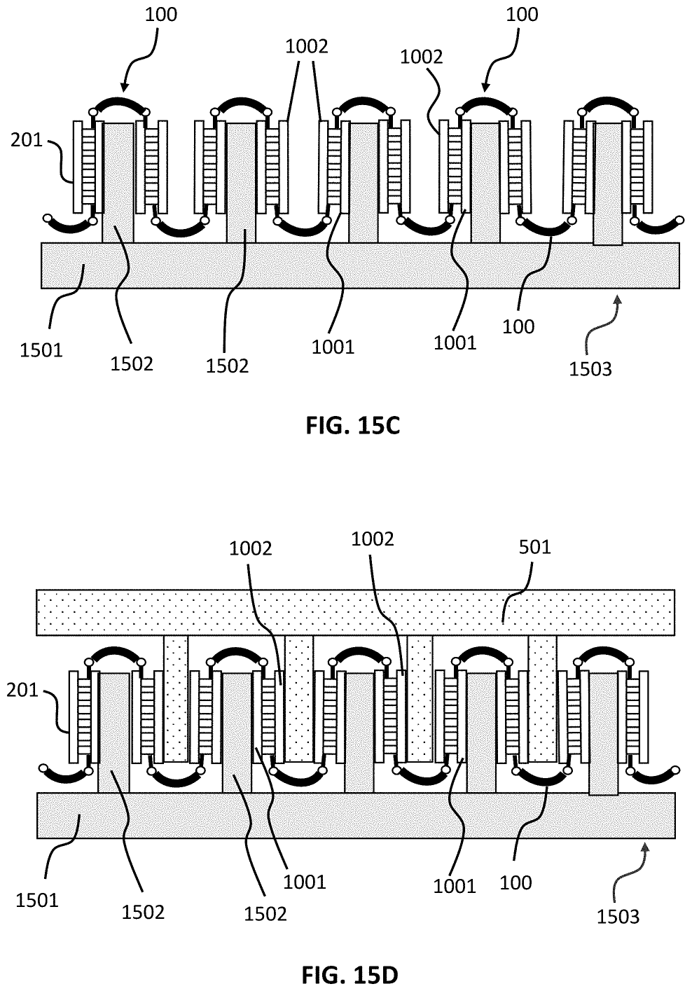

FIGS. 15A-15D illustrate the conformability of TEDs 200 comprising a plurality of TEMs 201. The embodiments shown here comprise a plurality of TEMs 201 electrically and mechanically coupled with electrically conductive connectors 100. FIG. 15A depicts a linear arrangement of TEMs 201 in a planar configuration and is an end view facing TEM ends 202 (as for end views in FIGS. 5B-5E). In many embodiments, rotatable coupling of TEMs 201 and elastic deformation of electrically conductive connector 100 may enable and enhance the ability of a TED 200 to conform with an irregularly shaped or non-planar surface or object. FIG. 15B depicts the TEMs 201 shown in FIG. 15A in a folded arrangement. FIG. 15C illustrates TEMs 201 connected by electrically conductive connectors 100 and positioned for cooling of protruding structures 1502 of irregularly shaped object 1501. In this configuration, cold sides 1001 of TEMs 201 are positioned against protruding structures 1502, and hot sides 1002 of TEMs 201 discharge heat into the spaces between protruding structures 1502. In some embodiments, this configuration may be especially useful for achieving high efficiency heat transfer in applications which require high heat flux per unit area. In some aspects, irregularly shaped object 1501 may itself be positioned to be near or in contact with a separate surface or object to be cooled, and heat can be transferred from the separate surface or object to irregularly shaped object 1501 thence to TEMs 201 to be discharged from hot sides 1002 of TEMs 201. For example, in the embodiment shown in FIG. 15C flat side 1503 of irregularly shaped object 1501 may be positioned near or in contact with the separate surface or object that is to be cooled.

In some embodiments, as illustrated in FIG. 15D, a heat dissipation structure 501 having fins may be positioned between TEMs 201 so that the fins form an interdigitated assembly with protruding regions 1502 and TEMs 201. In yet another aspect, heat dissipation structure 501 may be positioned to be contact with yet another separate surface or with a thermal interface material 1205 to further increase the efficiency of heat transfer. Therefore, in many embodiments, rotatable coupling of TEMs 201 and elastic deformation of electrically conductive connector 100 may enable and enhance the ability of a TED 200 to conform with an irregularly shaped or non-planar heat dissipation structure 501. Any of these embodiments may be useful for providing high thermal transfer per unit area, thereby increasing cooling efficiency of irregularly-shaped object 1501.

It is specifically contemplated that embodiments of electrically conductive connectors, TEMs, and TEDs described herein may comprise the elements described herein in various different combinations and numbers. In various embodiments of TEDs, not all elements or types of elements need be the same or have the same characteristics or parameters. Other objects, features, and advantages of the embodiments described herein will become apparent from the detailed description. It should be understood, however, that the detailed description and the specific examples, while indicating specific embodiments, are given by way of illustration only, since various changes and modifications within the spirit and scope of the invention will become apparent to those skilled in the art from this detailed description.

What is claimed is:

1. A thermoelectric device comprising:
a plurality of electrically connected thermoelectric modules, wherein at least a first and a second thermoelectric modules are electrically and mechanically connected by an electrically conductive connector, the electrically conductive connector being a compliant mechanism and comprising a first connecting region connected to a first thermoelectric module, a second connecting region connected to a second thermoelectric module, and an elastically deformable region between the first connecting region and the second connecting region, wherein at least one of the first or second connecting regions is releasably and rotatably connected to the respective first or second thermoelectric module.

2. The thermoelectric device of claim 1, wherein the first connecting region is releasably and rotatably connected to the first thermoelectric module and the second connecting region is fixedly connected to the second thermoelectric module.

3. The thermoelectric device of claim 1, wherein the first and second connecting regions are releasably and rotatably connected to the respective first and second thermoelectric modules with a plug-receptacle connection.

4. The thermoelectric device of claim 1 wherein the at least first and second thermoelectric modules comprise thermally conductive substrates that are printed circuit boards.

5. The thermoelectric device of claim 1 wherein at least one of the first and second thermoelectric modules is positioned in a carrier frame.

6. A medical device comprising the thermoelectric device of claim 1.

7. An article of apparel comprising the thermoelectric device of claim 1.

8. The thermoelectric device of claim 1, wherein the at least first and second thermoelectric modules are electrically and mechanically connected by a plurality of electrically conductive connectors, each of the plurality of electrically conductive connectors being a compliant mechanism and comprising a first connecting region connected to the first thermoelectric module, a second connecting region connected to the second thermoelectric module, and an elastically deformable region between the first connecting region and the second connecting region, wherein the first connecting region in each of the plurality of electrically conductive connectors is releasably and rotatably connected to the first thermoelectric module.

9. The thermoelectric device of claim 8, wherein the second connecting region in each of the plurality of electrically conductive connectors is releasably and rotatably connected to the second thermoelectric module.

10. The thermoelectric device of claim 8, wherein the second connecting region in each of the plurality of electrically conductive connectors is non-rotatably connected to the second thermoelectric module.

11. The thermoelectric device of claim 10, wherein the second connecting region in each of the plurality of electrically conductive connectors is releasably connected to the second thermoelectric module.

12. The thermoelectric device of claim 10, wherein the second connecting region in each of the plurality of electrically conductive connectors is fixedly connected to the second thermoelectric module.

13. The thermoelectric device of claim 1, wherein the at least one of the first or second connecting regions is releasably and rotatably connected to the respective first or second thermoelectric module with a plug-receptacle connection.

14. The thermoelectric device of claim 13, wherein the at least one of the first and second connecting regions is configured as a plug.

15. The thermoelectric device of claim 13, wherein the at least one of the first and second connecting regions is configured as a receptacle.

16. The thermoelectric device of claim 13, wherein the plug-receptacle connection is rotatable around a longitudinal axis of the receptacle.

17. The thermoelectric device of claim 1, wherein the at least first and second thermoelectric modules are electrically and mechanically connected by a plurality of electrically conductive connectors, each electrically conductive connector in the plurality of electrically conductive connectors being a compliant mechanism and comprising a first connecting region connected to the first thermoelectric module, a second connecting region connected to the second thermoelectric module, and an elastically deformable region between the first connecting region and the second connecting region in each of the plurality of electrically conductive connectors, wherein the first connecting region in each of the plurality of electrically conductive connectors is releasably and rotatably connected to the at least first thermoelectric module.

18. The thermoelectric device of claim 17, wherein the second connecting region in each electrically conductive connector of the plurality of electrically conductive connectors is releasably and rotatably connected to the at least second thermoelectric modules.

19. The thermoelectric device of claim 1 further comprising at least one heat dissipation structure.

20. The thermoelectric device of claim 19 further comprising at least one fan.

21. A thermoelectric device comprising:
a plurality of electrically connected thermoelectric modules, wherein at least a first and a second thermoelectric modules are electrically and mechanically connected by an electrically conductive connector, the electrically conductive connector being a compliant mechanism and comprising a first connecting region connected to a first thermoelectric module, a second connecting region connected to a second thermoelectric module, and an elastically deformable region between the first connecting region and the second connecting region, wherein the first and second connecting regions are fixedly connected to the respective first and second thermoelectric modules.
